(19) United States
(12) Patent Application Publication
(10) Pub. No.: US 2024/0321720 A1
(43) Pub. Date: Sep. 26, 2024

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Yuki YANO, Tokyo (JP); Yoji KAWAUCHI, Tokyo (JP)

(73) Assignee: Mitsubishi Electric Corporation, Tokyo (JP)

(21) Appl. No.: 18/577,884

(22) PCT Filed: Sep. 17, 2021
(86) PCT No.: PCT/JP2021/034308

§ 371 Date: Jan. 9, 2024

(51) Int. Cl. H01L 23/498; H01L 23/00; H01L 25/07

(52) U.S. Cl. CPC H01L 23/49844; H01L 23/49822; H01L 24/32; H01L 25/072; H01L 2224/32225; H01L 2224/32245; H01L 2924/3511

(57) ABSTRACT

A semiconductor device includes an insulating substrate having a circuit pattern, a plurality of semiconductor elements bonded onto the circuit pattern via first bonding portions, and a lead electrode to which each of the plurality of semiconductor elements is bonded via a second bonded portion, wherein the lead electrode is composed of a plurality of lead electrode pieces crossing at least one semiconductor element of the plurality of semiconductor elements, and the plurality of lead electrode pieces are bonded to each other via third bonded portions.

### TECHNICAL FIELD

The present disclosure relates to a semiconductor device and a method of manufacturing the semiconductor device.

A semiconductor device that has a Direct Lead Bonding (DLB) structure in which lead electrodes are directly bonded to semiconductor elements by solder to connect the semiconductor elements and internal circuits within a module to external circuits outside the module. The semiconductor device having the DLB structure can have a larger cross-sectional area of the electrode than when using a thin bonding wire, so higher current capacity, longer lifespan, and greater reliability can be realized.

In the semiconductor device with the DLB structure, long lead electrodes are bonded across a plurality of semiconductor elements, when warping occurs in an insulating substrate on which the semiconductor elements are mounted due to heating and cooling, variations in the spacing between the semiconductor elements and the lead electrodes, making it more susceptible to poor bonding.

Therefore, a technique that improves the reliability of bonding between the semiconductor elements and the lead electrodes are being considered. For example, in Patent Document 1, the lead electrode is provided with an opening corresponding to the mounting position of the semiconductor element, the bonded component is placed within the opening and the outer periphery of the semiconductor element is bonded to the inner periphery of the opening, thereby obtaining the structure that is insusceptible to the effects of warping of the insulating substrate on which semiconductor elements are mounted.

### PRIOR ART DOCUMENTS

### Patent Document(s)

[Patent Document 1] International Publication No. 2021/075016

### SUMMARY

### Problem to be Solved by the Invention

However, in Patent Document 1, although the bonded component is movable during heating, when the step near the opening of the lead electrode is used to support the step of the bonded component inside the opening, the movement of the bonded component is restricted; therefore, there is a problem in that a sufficient bonding area between the semiconductor element and the lead electrode cannot be secured, especially when the insulating substrate has a large warp deformation.

The present disclosure has been made to solve the above-mentioned problem, and an object thereof is to provide a semiconductor device and a manufacturing method in which a sufficient bonding area between a semiconductor element and a lead electrode is secured.

### Means to Solve the Problem

According to the present disclosure a semiconductor device includes an insulating substrate having a circuit pattern, a plurality of semiconductor elements bonded onto the circuit pattern via first bonding portions, and a lead electrode to which each of the plurality of semiconductor elements is bonded via a second bonded portion, wherein the lead electrode is composed of a plurality of lead electrode pieces crossing at least one semiconductor element of the plurality of semiconductor elements, and the plurality of lead electrode pieces are bonded to each other via third bonded portions.

According to the present disclosure, a method of manufacturing a semiconductor device, includes a first bonding material placing step of placing a first bonding material on a circuit pattern provided on an insulating substrate at a position where a semiconductor element is to be mounted, a semiconductor element placing step of placing a plurality of semiconductor elements on the first bonding material: a second bonding material placing step of placing a second bonding material on each of the semiconductor elements, a lead electrode piece placing step of placing a plurality of lead electrode pieces composing the lead electrode on the second bonding material, a third bonding material placing step of placing a third bonding material on the plurality of lead electrode pieces, and a bonding material heating step of heating the first bonding material, the second bonding material, and the third bonding material.

### Effects of the Invention

According to the present disclosure, the lead electrode to be bonded to the upper surface of the semiconductor elements is composed of a plurality of lead electrode pieces, and the plurality of lead electrode pieces are bonded to each other with a bonding material, which allows the lead electrode pieces to move following the warpage of the insulating substrate; thereby securing sufficient bonding areas between the semiconductor elements and the lead electrode.

### BRIEF DESCRIPTION OF DRAWINGS

FIG. 1 A cross-sectional view illustrating a schematic configuration of a semiconductor device according to Embodiment 1.

FIG. 2 A top view illustrating part of the configuration of the semiconductor device according to Embodiment 1.

FIG. 3 A flowchart illustrating a manufacturing process of the semiconductor device according to Embodiment 1.

FIG. 4 A schematic diagram illustrating a heated state of the semiconductor device according to Embodiment 1.

FIG. 5 A schematic diagram illustrating a heated state of a semiconductor device for comparison.

FIG. 6 A top view illustrating a schematic configuration of a semiconductor device according to Embodiment 2.

FIG. 7 A top view illustrating an end portion of the lead electrode piece according to Embodiment 2.

FIG. 8 A top view illustrating a schematic configuration of a semiconductor device according to Embodiment 3.

FIG. 9 A top view illustrating a schematic configuration of a semiconductor device according to Embodiment 4.

FIG. 10 A diagram illustrating a heated state of the semiconductor device according to Embodiment 4.

FIG. 11 A top view illustrating an end portion of the lead electrode piece according to Embodiment 4.

### DESCRIPTION OF EMBODIMENT(S)

### Embodiment 1

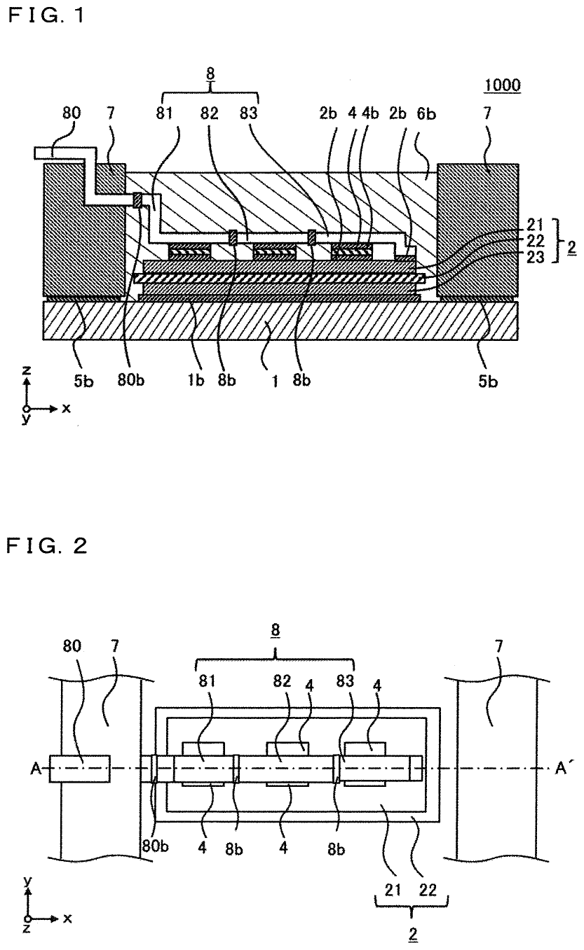

A semiconductor device 1000 in Embodiment 1 will be described referring to FIGS. 1 to 5.

FIG. 1 is cross-sectional view illustrating a schematic configuration of the semiconductor device according to Embodiment 1. FIG. 2 is top view illustrating part of the configuration of the semiconductor device according to Embodiment 1. Further, FIG. 1 illustrates the A-A′ cross section in FIG. 2. In FIGS. 1 and 2, the schematic configuration of the semiconductor device 1000 is illustrated, and signal lines, wires, signal terminals, and the like, for electrical connection with a semiconductor element 4 are omitted.

As illustrated in FIGS. 1 and 2, the semiconductor device 1000 according to Embodiment 1 includes a base plate 1, an insulating substrate 2, a semiconductor element 4, a lead electrode 8, and a case 7.

The base plate 1 is made of a material with excellent thermal conductivity, such as an aluminum alloy or copper, for example. The base plate 1 has flat front and back surfaces and a plate-like shape, and supports the insulating substrate 2 on which a plurality of semiconductor elements 4 are mounted, and the case 7. For example, fins or the like may be provided on the back surface of the base plate 1 for improving the cooling performance of the semiconductor device 1000.

The insulating substrate 2 is bonded to the front surface of the base plate 1 using a bonding material for bonding base plate. In the insulating substrate 2, circuit patterns 21 and 23 made of metal such as an aluminum alloy or copper are formed on an insulating layer 22 made of ceramic such as aluminum nitride, silicon nitride, or resin such as epoxy resin. The back surface of the insulating substrate 2 is bonded to the front surface of the base plate 1 using plate solder, solder paste, soft solder, or the like, which form a base plate bonded portion 1b.

The plurality of semiconductor elements 4 are bonded to a circuit pattern 21 of the upper insulating substrate 2 via a first bonding material such as plate solder, solder paste, soft solder, or the like, and a first bonded portion 2b is formed between the insulating substrate 2 and each of the semiconductor elements 4.

The semiconductor element 4 is, for example, an Insulated Gate Bipolar Transistor (IGBT) made of silicon (Si), a diode, or a reverse conduction IGBT. A Metal Oxide Semiconductor Field Effect Transistor (MOSFET) made of a material with a larger band gap than Si, such as silicon carbide (SiC) or gallium nitride (GaN), a Schottky diode, or the like may also be adoptable.

Further, the number of semiconductor elements 4 to be mounted on the insulating substrate 2 is not limited, and a required number of semiconductor elements 4 may be mounted depending on the application.

As illustrated in FIG. 2, the lead electrode 8 is composed of lead electrode pieces 81, 82, and 83 that are separated at positions where the semiconductor elements 4 are not mounted in top view, and the lead electrode pieces 81, 82, and 83 are bonded to the semiconductor elements 4 via second bonded portions 4b. It is also electrically connected to the circuit pattern 21 on the insulating substrate 2. The lead electrode pieces 81, 82, and 83 composing the lead electrode 8 are formed in a manner of, for example, separating the long lead electrode 8 in the lateral direction. The separation plane is perpendicular to the upper surface of the lead electrode 8.

Further, the lead electrode pieces 81, 82, and 83 are bonded at the separation surfaces with a third bonding material such as plate solder or a solder paste, and a third bonded portion 8b is formed between each separation surface. The third bonded portion 8b has bonding surfaces with the lead electrode pieces 81, 82, and 83 in the lateral direction of the lead electrode 8, and the bonding surfaces are perpendicular to the upper surface of the lead electrode 8. The lead electrode pieces 81, 82, and 83 are composed of, for example, copper, a copper alloy, or the like, and electrically connect the semiconductor elements 4 and an external electrode 80 to each other.

The lead electrode 8 may be separated for each semiconductor element 4 to form lead electrode pieces 81, 82, 83, or, for example, some lead electrode pieces 81 and 82 may not be separated and may remain connected, and be separated from the lead electrode piece 83. That is, one lead electrode piece may exist on a plurality of semiconductor elements 4.

The external electrode 80 is bonded to the lead electrode piece 81 of the lead electrode 8 using a bonding material for bonding external electrode such as plate solder, solder paste, soft solder, etc. and an external electrode bonded portion 80b is formed between the external electrode 80 and the lead electrode piece 81.

The case 7 accommodates the insulating substrate 2 on which the semiconductor elements 4 are mounted, serves as a framework when a sealing resin is poured, and is formed of, for example, Polyphenylenesulfide (PPS). The case 7 is, for example, insert-molded with the external electrode 80 as an insert component, taking the configuration of the external electrode 80 being inserted into the case 7. The case 7 is adhered onto the base plate using a silicone-based or epoxy-based adhesive.

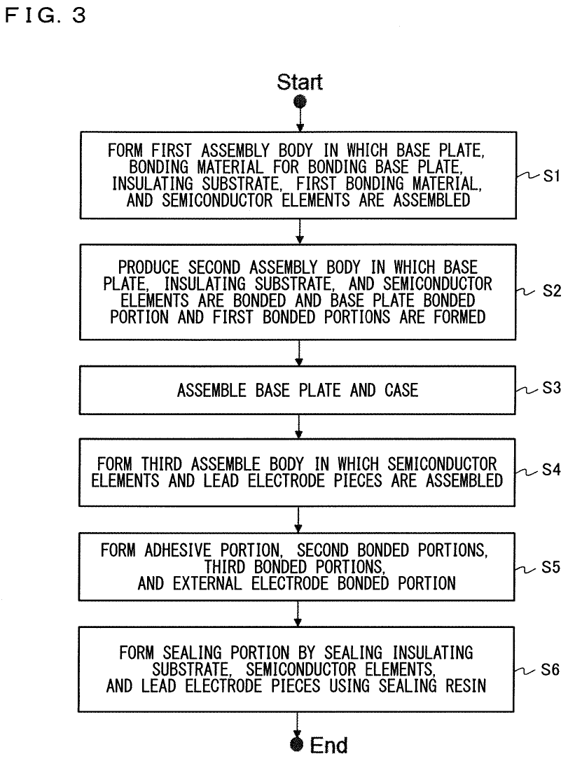

A method of manufacturing the semiconductor device 1000 in Embodiment 1 will be described referring to FIG. 3.

In Step S1, the base plate 1, the insulating substrate 2 on which circuit patterns 21 and 23 are formed on both sides of the insulating layer 22, and the semiconductor elements 4 are prepared. The bonding material for bonding base plate such as plate solder is placed on the base plate 1, the insulating substrate 2 is mounted on the bonding material for bonding base plate, on the mounting positions of the semiconductor elements 4 on the insulating substrate 2, for example, the first bonding material, such as plate solder, is placed equal to the number of semiconductor elements 4, and the semiconductor element 4 is placed on each thereof. The semiconductor element 4 is placed on an electrode pad of the circuit pattern 21 on the front surface of the insulating substrate 2.

Here, the example has been described in which solid plate solder is used as the bonding material for bonding base plate and the first bonding material, and the plate solder is placed, however, liquid solder paste may be used as the bonding material for bonding base plate and the first bonding material, and may be applied to required locations by screen printing. A liquid solder paste may be used and dripped onto the required locations using a dispenser.

In this manner, a first assembly body is formed in which the base plate 1, the bonding material for bonding base plate, the insulating substrate 2, the first bonding material, and the semiconductor elements 4 are assembled.

In Step S2, the first assembly body assembled in Step S1 is placed in a reflow oven and heated to a temperature equal to or higher than the melting points of the bonding material for bonding base plate and the first bonding material. The temperature of the reflow oven is raised to about 270° C., which is higher than the melting point of the bonding material for bonding base plate and the first bonding material, to melt the bonding material for bonding base plate and the first bonding material. After heating for a certain period of time, the bonding material for bonding base plate and the first bonding material are solidified by cooling.

In this manner, a second assembly body is produced in which the base plate 1, the insulating substrate 2, and the semiconductor elements 4 are bonded to form the base plate bonding portion 1b and the first bonding portions 2b.

In Step S3, surround the insulating substrate 2 of the second assembly body produced in Step S2, and the lower part of the case 7 in which the external electrode 80 is insert-molded is adhered onto the base plate 1 so that the external electrode 80 is in a predetermined position. For example, a silicone-based or epoxy-based material may be used as the adhesive. An adhesive portion 5b is formed between the base plate 1 and the case 7. The base plate 1 and the case 7 may be fastened together using a fastener such as screws. In this how the base plate 1 and the case 7 are assembled.

In Step S4, a second bonding material such as solder paste is applied onto the plurality of semiconductor elements 4, the lead electrode pieces 81, 82, and 83 are placed on the locations where the second bonding material is applied, in line with the position of the external electrodes 80 attached in Step S3. Next, in order to connect the external electrode 80 and the lead electrode piece 81, the lead electrode piece 81 and the lead electrode piece 82, and the lead electrode piece 82 and the lead electrode piece 83, a third bonding material such as solder paste and a bonding material for bonding external electrode are applied to each end by dispensing, for example.

The lead electrode pieces 81, 82, and 83 are connected to form the lead electrode 8, which may be prepared in the form of a plate of copper, copper alloy, etc. being cut in pieces in advance, or adjacent lead electrode pieces 81, 82, and 83 being made by stamping and cutting in such a manner that they are partially connected.

In this manner, a third assembly body is formed in which the semiconductor elements 4 and the lead electrode pieces 81, 82, and 83 are assembled.

Next, in Step S5, the third assembly body formed in Step S4 is heated to cure the adhesive, the second bonding material, the third bonding material, and the bonding material for bonding external electrode are melted, and the adhesive portion 5b, the second bonding portions 4b, the third bonding portion 8b, and the external electrode bonded portion 80b are formed.

Next, in Step S6, after wire bonding for signal circuit connection is performed, the insulating substrate 2, the semiconductor elements 4, the lead electrode pieces 81, 82, and 83, etc. in the case 7 are sealed using the sealing resin, and a sealing portion 6b is formed by heating and curing in an oven at 100° C. for 2 hours and at 140° C. for 2 to 3 hours, for example. For example, epoxy resin can be used as the sealing resin, but it is not limited thereto. Any material that suffices desired physical properties such as elastic modulus, heat resistance, adhesiveness, linear thermal expansion coefficient, etc. may be used.

In addition to Steps S1 to S6, necessary electrical characteristics and the like are inspected to complete the semiconductor device 1000.

As described above, in the manufactured semiconductor device 1000, the lead electrode 8 is moveable with the lead electrode 8 following the warping deformation caused in the heating step; therefore, even after the warping deformation of the insulating substrate 2 is removed, the semiconductor elements 4 and the lead electrode 8 are securely bonded with sufficient bonding areas between the semiconductor elements 4 and the lead electrode 8.

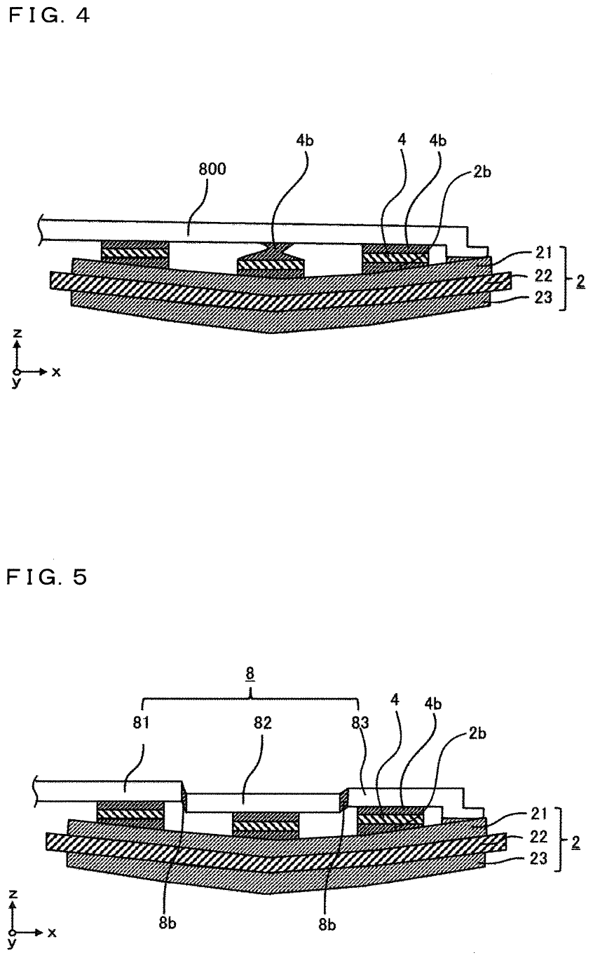

To be more specific, in the heating step in Step S5, warping deformation occurs due to the difference in linear thermal expansion coefficient of each member, making the distance between each semiconductor element 4 and lead electrode 8 in the z-axis direction inconsistent. When a solid long-length lead electrode 800 is placed on the upper surface of a plurality of semiconductor elements 4, as illustrated in FIG. 4, a semiconductor element 4 does not follow the warping deformation of the insulating substrate 2 during heating, leading to the smaller cross-sectional area of any of the second bonded portion 4b or a broken wire. Whereas, composing the lead electrode 8 of a plurality of lead electrode pieces 81, 82, and 83, and bonding the lead electrode pieces 81, 82, and 83 to each other using the third bonding material, allows each lead electrode piece 81, 82, and 83 to move individually in the z-axis direction following the warping deformation of the insulating substrate 2 during heating; therefore, as illustrated in FIG. 5, a sufficient bonding area between each semiconductor element 4 and the plurality of lead electrode pieces 81, 82, and 83, that is, the lead electrode 8, can be secured, leading to stable bonding.

Note that the example has been described of melting the bonding material for bonding base plate and the first bonding material of the first assembly body assembled in Step S1 in Step S2, and melting the second bonding material, the third bonding material, and external electrode bonding portion 80b of the third assembly body assembled in Step S4 in Step S5, however, the first to third assembly bodies assembled in advance and heated in the same Step may also be adoptable.

Also, the example of bonding of the first assembly body and of the third assembly body in Step S2 and Step S5, respectively, has been described, however, they may be temporarily fixed by preheating, or may be fixed by using the thixotropy of the solder paste.

Further, in Step S4, the example of the third bonding material being applied as solder paste using a dispenser has been described, however, plate solder may also be adoptable.

A process has been described in which in Step S4, the lead electrode pieces 81, 82, and 83 and the third bonding material are placed on the second bonding material on the plurality of semiconductor elements 4, the external electrode 80 and the lead electrode piece 81 are connected with the bonding material for bonding external electrode, and then, in Step S5, the third bonding material and the bonding material for bonding for external electrode are heated, however, the lead electrode 8, in which the external electrode 80 and lead electrode pieces 81, 82, and 83 are bonded via the external electrode bonded portion 80b and the third bonded portions 8b, may be inserted into the case 7 in advance.

The melting points of the first bonding material for bonding the semiconductor elements 4 and the electrode pads of the insulating substrate 2, the second bonding material for bonding the semiconductor elements 4 and the lead electrode pieces 81, 82, and 83, and the third bonding material for bonding the lead electrode pieces 81, 82, and 83 may or may not be the same. It is preferable that the melting point of the third bonding material is lower than that of the first bonding material and the second bonding material because the bonding state of the semiconductor elements 4 is not impaired in the heating step of the third bonding material.

Also, in FIGS. 1 and 2, the third bonded portions 8b have a rectangular parallelepiped shape having a surface perpendicular to the upper surfaces of the lead electrode pieces 81, 82, and 83 and a horizontal surface, however, the shape may take on a T-shape to cover the upper surfaces of 81, 82, and 83. The third bonded portions 8b may have a spherical upper surface as well.

Further, the example of configuring the semiconductor device 1000 using the base plate 1 and the case 7 has been described, however, the insulating substrate 2, the semiconductor elements 4, and the plurality of lead electrode pieces 81, 82, and 83 may be sealed by the sealing portion 6b formed by transfer molding.

Also, in FIG. 1, the example has been described in which the external electrode bonded portion 80b is provided between the end portion of the lead electrode piece 81 and the external electrode 80, however, the outer electrode 80 and the lead electrode pieces 81 may be continuous without the third bonded portion 8b as long as the warping deformation at the center of the insulating substrate 2 can be followed by the third bonded portions 8b provided between the lead electrode piece 81 and the lead electrode piece 82, and between the lead electrode piece 82 and the lead electrode piece 83. As described above, the number of third bonded portions 8b may be one or two or more.

In addition, the example have been described in which the lead electrode pieces 81, 82, and 83 composing the lead electrode 8 are formed by separating the long-length lead electrode 8 in the lateral direction, and the separation plane is perpendicular to the upper surface of the lead electrode 8, however, the separation plane may be slightly inclined from the direction perpendicular to the longitudinal direction of the lead electrode 8.

In this manner, even when some configurations are changed, the semiconductor device 100 can be manufactured by a first bonding material placing step of placing the first bonding material on the circuit patterns 21 and 23 provided on the insulating substrate 2 at the positions where the semiconductor elements 4 are to be mounted, a semiconductor element placing step of placing a plurality of semiconductor elements 4 on the first bonding material, a second bonding material placing step of placing the second bonding material on each semiconductor element 4, a lead electrode piece placing step of placing a plurality of lead electrode pieces 81, 82, and 83 composing the lead electrode 8 on the second bonding material, a third bonding material placing step of placing the third bonding material on the plurality of lead electrode pieces 81, 82, and 83, and a bonding material heating step of heating the first bonding material, the second bonding material, and the third bonding material.

Alternatively, the heating of at least one of the first bonding material, the second bonding material, and the third bonding material in the bonding material heating step may be performed as a separate step, and the assembly body may be sequentially produced. As described earlier, it is also adoptable that the third bonding material placing step of placing the third bonding material on the plurality of lead electrode pieces 81, 82, and 83 is performed first, and the lead electrode pieces 81, 82, and 83 are prepared in a connected state, and the connected lead electrode pieces 81, 82, and 83 is placed after the first bonding material placing step, the semiconductor element placing step, and the second bonding material placing step.

### Embodiment 2

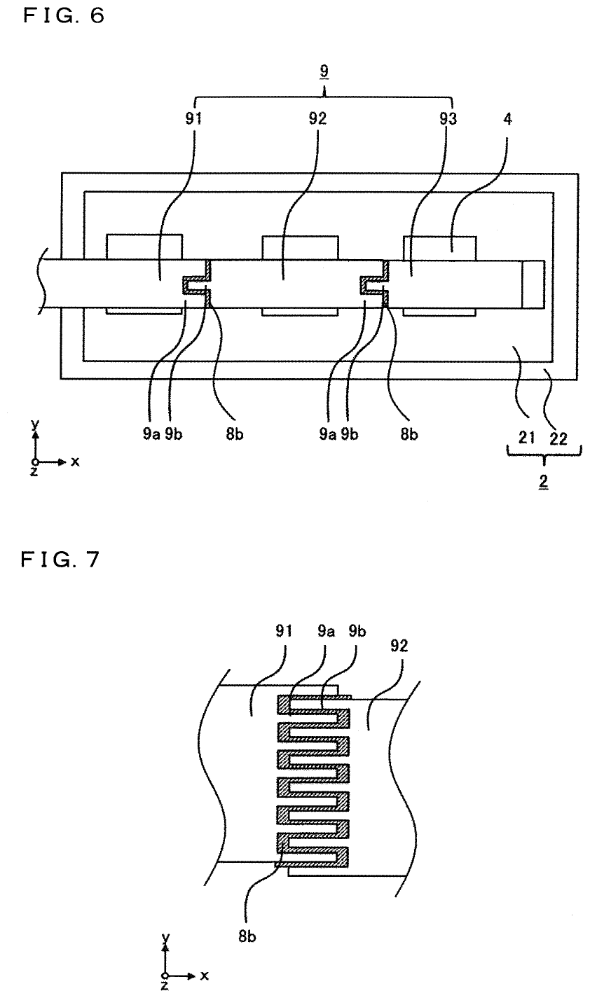

A semiconductor device 1000 in Embodiment 2 will be described referring to FIG. 6.

FIG. 6 is top view illustrating part of a configuration of the semiconductor device 1000 according to Embodiment 2.

In Embodiment 1, although the configuration has been described in which the long-length lead electrode 8 is linearly separated into the lead electrode pieces 81, 82, and 83 in the lateral direction, and the third bonded portions 8b are provided at the separation planes perpendicular to the upper surface of the lead electrode 8, Embodiment 2 differs in that the end portions of lead electrode pieces 91, 92, and 93 are concave or convex. Configurations other than that are the same as Embodiment 1.

As illustrated in FIG. 6, in top view, one end portion of the adjacent lead electrode pieces 91, 92, and 93 of the lead electrode 9 has a concave portion 9a, and an other end portion has a convex portion 9b, the concave portion 9a and the convex portion 9b are engaged with each other, and they are bonded at separation planes perpendicular to the upper surface of the lead electrode 9 by the third bonding material. More specifically, as illustrated in FIG. 6, the concave portion 9a on the right end portion of the lead electrode piece 91 and the convex portion 9b on the left end portion of the lead electrode piece 92 are engaged with each other, the concave portion 9a on the right end portion of the lead electrode piece 92 and the convex portion 9b on the left end portion of the lead electrode piece 93 are engaged with each other, and each of them is bonded by a third bonding material at the separation planes perpendicular to the upper surface of the lead electrode 9.

In this manner, in the semiconductor device 1000 according to Embodiment 2, composing the lead electrode 9, which is bonded on the upper surfaces of the semiconductor elements 4, of a plurality of lead electrode pieces 91, 92, and 93, and bonding the lead electrode pieces 91, 92, and 93 to each other using the third bonding material, allows each lead electrode piece 91, 92, and 93 to move individually in the z-axis direction following the warping deformation of the insulating substrate 2 during heating. Therefore, securing sufficient bonding areas between the semiconductor elements 4 and the lead electrode 8 is ensured.

Further, compared to the case where the end portions of the lead electrode pieces 81, 82, and 83 are linear, the bonding area of the third bonded portion 8b is larger. Therefore, the melted third bonding material is prevented from falling onto the insulating substrate 2 due to the surface tension when the third bonding material is melted.

Also, as illustrated in FIG. 6, even when the lead electrode pieces 91, 92, and 93 move in the y-axis direction when the third bonding material is melted, the movement of the lead electrode pieces 91, 92, and 93 is restricted because the engagement of the concave portions 9a and the convex portions 9b, enabling to prevent the lead electrode pieces 91, 92, and 93 from shifting in the y-axis direction.

The example has been illustrated referring to FIG. 6 in which a pair of the concave portion 9a and the convex portion 9b are engaged with each other, however, a formation in which a plurality of concave portions 9a and convex portions 9b are engaged with each other as illustrated in FIG. 7 may also be adoptable.

When a form of a plurality of concave portions 9a and convex portions 9b are engaged with each other is adopted, the bonding area by the third bonded portion 8b larger than when a pair of the concave portion 9a and the convex portion 9b are engaged with each other. Therefore, the melted third bonding material is prevented from falling onto the insulating substrate 2 due to the surface tension when the third bonding material is melted.

Further, the example has been illustrated in which the right end portions of the lead electrode pieces 91 and 92 have the concave portion 9a, and the left end portions of the lead electrode pieces 92 and 93 have the convex portion 9b, however, the right and left end portions may be reversed.

### Embodiment 3

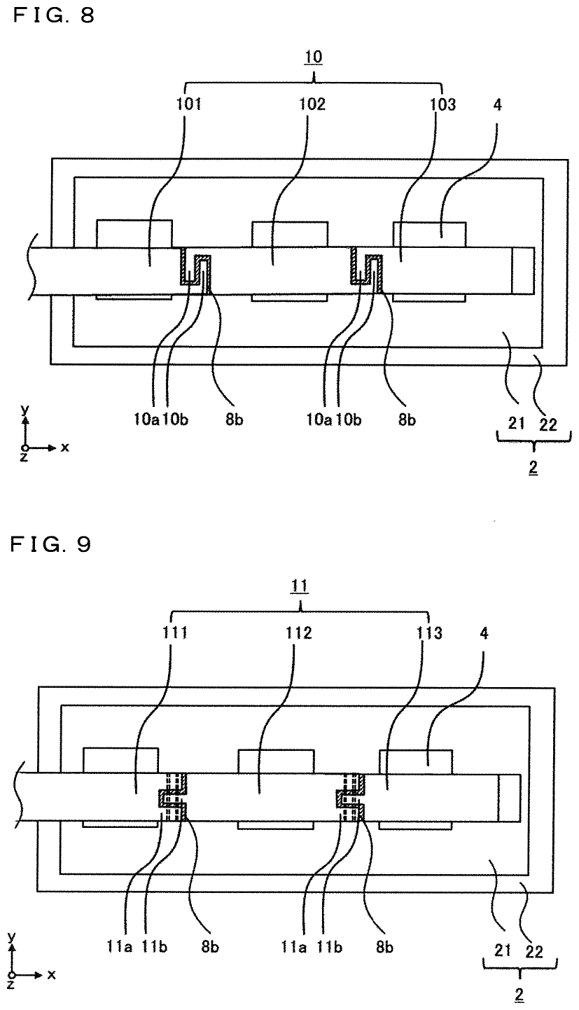

A semiconductor device 1000 in Embodiment 3 will be described referring to FIG. 8.

FIG. 8 is top view illustrating part of a configuration of the semiconductor device 1000 according to Embodiment 3.

In Embodiment 1, although the configuration has been described in which the long-length lead electrode 8 is linearly separated into the lead electrode pieces 81, 82, and 83 in the lateral direction, and are bonded by the third bonding material at the separation planes perpendicular to the upper surface of the lead electrode 8, Embodiment 3 differs in that the end portions of lead electrode pieces 101, 102, and 103 have a hook shape. Configurations other than that are the same as Embodiment 1.

As illustrated in FIG. 8, in top view, one of the end portions of the adjacent lead electrode pieces 101, 102, 103 of the lead electrode 10 have a hook shape 10a, and other end portions have a hook shape 10b for hooking the hook shape 10a, the hook shape 10a and the hook shape 10b for hooking the hook shape 10a are engaged with each other, and are bonded at a separation plane perpendicular to the upper surface of the lead electrode 10 via the third bonded portion 8b. More specifically, as illustrated in FIG. 8, the hook shape 10a on the right end portion of the lead electrode piece 101 and the hook shape 10b on the left end portion of the lead electrode piece 102 are engaged with each other, and the hook shape 10a on the right end portion of the lead electrode piece 102 and the hook shape 10b on the left end portion of the lead electrode piece 103 are engage with each other; thereby, each thereof being bonded at the separation plane perpendicular to the upper surface of the lead electrode 10 via the third bonded portion 8b.

As described above, the semiconductor device 1000 according to Embodiment 3 includes the lead electrode 10, which is bonded to the upper surfaces of the semiconductor elements 4, is composed of the plurality of lead electrode pieces 101, 102, and 103, in which the plurality of lead electrode pieces 101, 102, and 103 are bonded with the third bonding materials with each other which allows each lead electrode piece 101, 102, and 103 to move individually in the z-axis direction following the warping deformation of the insulating substrate 2 and the base plate 1 during heating. Therefore, securing sufficient bonding areas between the semiconductor elements 4 and the lead electrode 10 is ensured.

Further, compared to the case where the end portions of the lead electrode pieces 81, 82, and 83 are a linear shape, the bonding area of the third bonded portion 8b is larger. Therefore, the melted third bonding material is prevented from falling onto the insulating substrate 2 due to the surface tension when the third bonding material is melted.

Further, even when the lead electrode pieces 101, 102, and 103 move in the x-axis direction when the third bonding material melts, the movement of the lead electrode pieces 101, 102, and 103 is restricted because the hook shape 10a and the hook shape 10b are engaged with each other, preventing the lead electrode pieces 101, 102, and 103 from shifting in the x-axis direction.

Note that, although the shape of the hook shape 10b for hooking the hook shape 10a is made to be the same shape as the hook shape 10a, the hook shape 10b may have any shape as long as it engages with the hook shape 10a.

Also, the example has been illustrated in which the right end portions of the lead electrode pieces 101 and 102 are the hook shape 10a, and the left end portions of the lead electrode pieces 102 and 103 are the hook shape 10b, however, the right and left end portions may be reversed.

### Embodiment 4

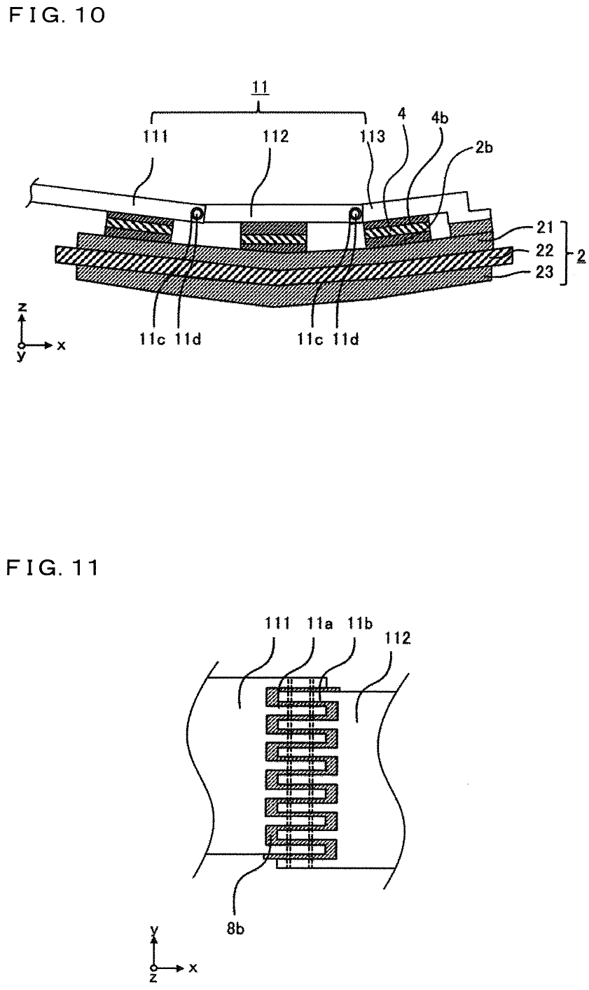

A semiconductor device 1000 in Embodiment 4 will be described referring to FIGS. 9 and 10.

FIG. 9 is top view illustrating part of a configuration of the semiconductor device 1000 according to Embodiment 4. FIG. 10 is a diagram illustrating a heated state of the semiconductor device according to Embodiment 4.

In Embodiment 2, the example of the end portion of the lead electrode piece being a concave shape or convex shape, and in Embodiment 3, the example of the end portion of the lead electrode piece being a hook shape have been described, and the distinction of Embodiment 4 therefrom lies in that a rotating shaft 11d is provided at the end portions of lead electrode pieces 111, 112, and 113. Configurations other than that are the same as Embodiments 2 and 3.

As illustrated in FIG. 9, in top view, the rotating shafts 11d are provided at the end portions of the adjacent lead electrode pieces 111, 112, and 113 of a lead electrode 11, and the lead electrode pieces 111, 112, and 113 are connected to each other. Also, they are bonded at the separation planes perpendicular to the upper surface of the lead electrode 11 via the third bonded portions 8b. More specifically, as illustrated in FIGS. 9 and 10, a concave portion 11a is formed at the right end portion of the lead electrode piece 111, and a convex portion 11b is formed at the left end portion of the lead electrode piece 112, the concave portion 11a of the lead electrode piece 111 and the convex portion 11b of the lead electrode piece 112 are engaged with each other, and a penetrating portion 11c passing through the concave portion 11a of the lead electrode piece 111 and the convex portion 11b of the lead electrode piece 112 is provided, into which the rotating shaft 11d is inserted. Also, a concave portion 11a is formed at the right end portion of the lead electrode piece 112, and a convex portion 11b is formed at the left end portion of the lead electrode piece 113, the concave portion 11a of the lead electrode piece 112 and the convex portion 11b of the lead electrode piece 113 are engage with each other, a penetrating portion 11c passing through the concave portion 11a of the lead electrode piece 112 and the convex portion 11b of the lead electrode piece 113 is provided, into which the rotating shaft 11d is inserted.

Each of them is bonded at the separation plane perpendicular to the upper surface of the lead electrode 11 via the third bonding material.

As described above, the semiconductor device 1000 according to Embodiment 4 includes the lead electrode 11, which is bonded to the upper surfaces of the semiconductor elements 4, is composed of the plurality of lead electrode pieces 111, 112, and 113, in which the plurality of lead electrode pieces 111, 112, and 113 are bonded with the third bonding materials with each other which allows each lead electrode piece 111, 112, and 113 to rotate individually and move in the z-axis direction following the warping deformation of the insulating substrate 2 during heating. Therefore, securing sufficient bonding areas between the semiconductor elements 4 and the lead electrode 11 is ensured.

Further, compared to the case where the end portions of the lead electrode pieces 81, 82, and 83 are a linear shape, the bonding areas bonded by the third bonding material are larger. Therefore, the melted third bonding material is prevented from falling onto the insulating substrate 2 due to the surface tension when the third bonding material is melted.

Also, as illustrated in FIG. 10, even when the lead electrode pieces 111, 112, and 113 move in the x- or y-axis direction when the third bonding material melts, the movement of the lead electrode pieces 111, 112, and 113 is restricted because the concave portions 11a and the convex portions 11b are fixed at the rotating shafts 11d by a hinge structure; therefore, preventing the lead electrode pieces 111, 112, and 113 from shifting in the x- and y-axis directions.

Although in FIG. 9, the example in which one pair of concave portion 11a and a convex portion 11b has been illustrated, a formation in which a plurality of concave and convex portions may overlap each other in a comb-like shape as illustrated in FIG. 11 may also be adoptable.

Also, the example has been illustrated in which the right ends of the lead electrode pieces 111 and 112 are the concave portions 11a, and the left ends of the lead electrode pieces 112 and 113 are the convex portions 11b, the left and right ends of the lead electrode pieces 111, 112, and 113 on which the concave portions 11a and the convex portions 11b are provided may be reversed.

Further, the rotating shaft 11d may be provided at the portion where the hook shape 10a and the hook shape 10b are engage with each other, or other shapes may be adoptable.

Further, although the example has been illustrated in which the adjacent lead electrode pieces 111, 112, and 113 are connected by providing the penetrating portions 11c at the end portions of the lead electrode pieces 111, 112, and 113 and inserting the rotating shaft 11d, it only suffices that lead electrode pieces 111, 112, and 113 are connected so as to rotate with each other.

In addition to the above, it is possible to freely combine each Embodiment, to modify any component of each Embodiment, or to omit any component of each Embodiment.

1. A semiconductor device comprising:
an insulating substrate having a circuit pattern;
a plurality of semiconductor elements bonded onto the circuit pattern via first bonded portions; and
a lead electrode to which each of the plurality of semiconductor elements is bonded via a second bonded portion, wherein
the lead electrode is composed of a plurality of lead electrode pieces crossing at least one semiconductor element of the plurality of semiconductor elements, and
the plurality of lead electrode pieces are bonded to each other via third bonded portions.

2. The semiconductor device according to claim 1, wherein
the third bonded portion has a bonding surface with the lead electrode piece in the lateral direction of the lead electrode, and the bonding surface is perpendicular to an upper surface of the lead electrode.

3. The semiconductor device according to claim 1, wherein
one of the adjacent lead electrode pieces has a concave portion, and an other has a convex portion, and
the concave portion and the convex portion are engaged with each other and bonded via the third bonded portion.

4. The semiconductor device according to claim 1, wherein
one of the adjacent lead electrode pieces has a hook shape, and an other has a shape that hooks the hook shape, and the hook shape and the shape that hooks are engaged with each other and bonded via the third bonded portion.

5. The semiconductor device according to claim 1, wherein
the adjacent lead electrode pieces are connected so as rotate with each other and bonded to each other via the third bonded portion.

6. The semiconductor device according to claim 1, wherein
an end portion of the at least one lead electrode piece of the plurality of lead electrode pieces is bonded to an external electrode via an external electrode bonded portion.

7. The semiconductor device according to claim 1, further comprising
a base plate to which the insulating substrate is bonded.

8. A method of manufacturing a semiconductor device, comprising:
a first bonding material placing step of placing a first bonding material on a circuit pattern provided on an insulating substrate at a position where a semiconductor element is to be mounted;
a semiconductor element placing step of placing a plurality of semiconductor elements on the first bonding material;
a second bonding material placing step of placing a second bonding material on each of the semiconductor elements;
a lead electrode piece placing step of placing a plurality of lead electrode pieces composing the lead electrode on the second bonding material;
a third bonding material placing step of placing a third bonding material on the plurality of lead electrode pieces; and
a bonding material heating step of heating the first bonding material, the second bonding material, and the third bonding material.

9. The method of manufacturing the semiconductor device according to claim 8, wherein
in the bonding material heating step, heating at least one of the first bonding material, the second bonding material, and the third bonding material is performed as a separate step, and an assembly body is sequentially produced.
